(19) United States
(12) Patent Application Publication
(10) Pub. No.: US 2003/0058707 A1
(43) Pub. Date: Mar. 27, 2003

(54) System and process for implementing commercial breaks in programming

(76) Inventors: Bruce C. Dilger, Medford, NJ (US); Michael G. Cristofalo, Doylestown, PA (US); Frank P. Deo, Flemington, NJ (US)

Correspondence Address: DORSEY & WHITNEY, LLP, INTELLECTUAL PROPERTY DEPARTMENT, 370 SEVENTEENTH STREET, SUITE 4700, DENVER, CO, 80202-5647, US

(21) Appl. No.: 10/241,025

(22) Filed: Sep. 10, 2002

Related U.S. Application Data
(60) Provisional application No. 60/322,901, filed on Sep. 12, 2001.

(51) Int. Cl. G11C 7/00

(52) U.S. Cl. 365/200

(57) ABSTRACT

A system and process is provided for determining, selecting and identifying commercial and/or non-commercial segments for insertion into a break in a given programming signal. In one embodiment, a break planner is provided in a media stream planner. The break planner utilizes at least one parameter provided by at least one of an ad campaign, an active segments list, a viewer profile database, and a prior inserts history to determine which segment to insert into a given break in a programming signal. Such determinations may be made real-time or on a pre-determined basis and may be communicated to an advertisement inserter which provides such “segments” to a transmission system for insertion into a transmitted or otherwise communicated programming signal. In an alternative embodiment, the selection and insertion processes may be accomplished in a personal video recorder.

### CROSS REFERENCE TO RELATED APPLICATIONS

The present application claims priority to and incorporates by reference, in its entirety, U.S. Provisional patent application Serial No. 60/322,901, filed on Sep. 12, 2001 in the name of Bruce C. Dilger and having the same title as the present application.

### FIELD OF THE INVENTION

The present invention relates to the field of commercial advertising. More specifically, the present invention relates to the scheduling and implementation of commercial advertisements during breaks in a programming signal.

BACKGROUND OF THE INVENTION

Today, millions of viewers of television, radio and other multi-media programming signals are exposed to commercial advertisements, public service announcements and other forms of “commercials” during the “airing” of the programming. These “commercials” are often the primary source of revenue for the development and distribution of the programming. As such, great value is often attached to the time, length, medium (e.g., television versus radio or the Internet), audience and the content of the underlying program during which the commercial is presented.

Commonly, the assessment of value for such commercials is based upon contractual terms that are specified in advance and include many of the before mentioned parameters of when a commercial is desired to be “aired”. These contractual terms are then utilized in developing a schedule for the “airing” of commercials during specific programs. This schedule is commonly developed at least one day in advance by a third party scheduling agency (i.e., an entity that is neither responsible for the development nor the transmission of the commercial).

One example of such a scheduling provider is the AdVision system developed by AdVision, Inc. (a subsidiary of ACTV, Inc.). The AdVision system utilizes a Media Stream Planner (MSP) to plan for the insertion of advertising into media streams. The MSP is used such that a schedule is ultimately produced and communicated to an advertisement insertion system which then autonomously follows a schedule that inserts advertising into a plurality of programming signals. FIG. 1 is one example of the prior art configuration of an AdVision system.

As shown in FIG. 1, one prior art system 100 utilize an MSP 104 which receives multiple advertising campaigns 102 that provide contractual requirements 101 for the placement of commercials in programming. The MSP 104 utilizes the received information to produce a commercial schedule 103 for the next day. The commercial schedule 103 is commonly provided to an Ad Inserter 108 a day prior to the “airing” of the commercials. However, in some instances schedules 103 are provided on less than full day increments, but not in real-time. The schedule is usually a sequence of fully qualified playback commands that are specified in a text file. These commands define the exact sequence of segments to be played at completely specified time periods.

Further, at the appropriate times during a programming signal 110, the Ad Inserter 108 inserts a segment 107 at a break point (i.e., a “break”) in the programming signal 111. The Ad Inserter 108 obtains the segment 107 from a database of digitally encoded segments 106. As is well known in the art, commercials are often provided in an analog format (for example, on tape) and converted into a digital format suitable for equipment utilized by separate broadcasters or cable head-ends. The digital encodings are then suitably saved on a memory device. The database 106 suitably stores such segments 107 as needed.

Further, the times at which the Ad Inserter 108 are to insert a commercial are commonly designated by Cue-Tones 119 provided in the programming signal 110. The programming 109 and segments 111 are also provided to a transmission system 112 which receives the programming 109 and inserts the segment(s) 111 into the transmission signal 113 at the desired break points. The transmission signal 113 (which contains the program and the commercials/segments inserted at the breaks) is then transmitted to the viewer for presentation upon a display 114 or similar presentation device.

Since numerous advertisers often compete for the same commercial slots in a program, great effort is often expended in trying to adhere, as best as possible, to the commercial schedule. For broadcasts of pre-recorded programs, such as, sit-coms, adherence to the schedule is often achievable. However, when live events are part of a day's line-up, adherence to the schedule can often become quite difficult, if not impossible. Since the schedule is rather inflexible, in that it is generated commonly at least one day in advance, the result is that for the prior art systems, commercials are not always “aired” at the designated times. Advertisers generally will not pay, or will only pay at a reduced rate, when a commercial is not aired at a scheduled time during a designated program. To determine the appropriate rate and to collect other information, detailed logging is accomplished of when a commercial is aired, the audience, the underlying program and other information by a segment insertion logging device 116. This logging is based upon information 115 received from the Ad Inserter 108 and is delivered to the MSP 104 as a prior inserts history 117 batch file on usually on a daily basis. The MSP 104 employs this information 117 in an attempt to “make good” on any commercials that were not presented as originally scheduled. Since the schedule is generated at least a day in advance, an attempt to “make good” usually can not occur until at least two days after the originally scheduled time for airing a commercial. In short, since the schedule is generated at least one day in advance, a two-day lag period usually occurs before a “missed” commercial can be rescheduled. Obviously, such a two-day lag period, for certain time-sensitive commercials, is often unacceptable and for other, not so time sensitive commercials, is highly undesirable. Thus, a better, more responsive system and process for scheduling commercials during programming is needed.

Further, in the prior art systems, the timing of breaks in programming are also scheduled in advance. This pre-scheduling of breaks is necessary in order to support the pre-scheduled timing of commercials. When live events are delayed (for example, a sporting event delayed due to weather or even pre-recorded events are interrupted (for example, for a then breaking news report), the breaks and corresponding commercial schedule are often placed in total disarray. Therefore, a more flexible system and method for designating commercial breaks, and scheduling and/or identifying commercials for such breaks is needed.

Further, not only are breaks and commercials to “air” during such breaks commonly scheduled days in advance, the content of the programming itself are also scheduled days, if not weeks, in advance. As mentioned previously, unexpected conditions may disrupt such schedules. These disruptions in the underlying programming schedule may also result in commercials being inserted in the wrong programs. Such improperly inserted commercials often are not paid for by advertisers. As such, revenue is often lost when programming schedule delays and/or changes occur. Therefore, a system and process which accommodates such interruptions by providing flexibility in scheduling is needed.

Additionally, with the advent of personal video recorders, for example, the TiVO system, it is common for programs to be recorded and then played-back at a later time with the viewer skipping any commercials originally inserted into the programming. This practice has the effect of decreasing the value of advertising and also makes it extremely difficult for advertisements to be timely presented in relation to a program and the time at which a program is actually presented to a viewer. For example, advertisements about a program immediately following a broadcast of current programming (for example, a live sporting event) are often meaningless when the live sporting event is being recorded and played back at a later time. The viewers of the recorded program, even if they can not skip through the advertisement, are generally disinterested in learning about programming that has already occurred. Thus, current scheduling systems for commercials in breaks in programming are often ineffective when the program is recorded and subsequently viewed at a later time by the viewer. Therefore, a system and process for determining real-time which segment(s) to insert into a given break in a programming signal is needed.

### SUMMARY OF THE INVENTION

At least one embodiment of the present invention provides a system and process for the real-time determination and scheduling of commercials or other segments during breaks in a programming signal. For example, a programming signal containing at least one of a news program, a sports program, a sit-com program, a featured presentation program, a movie, a drama program, a game show program, a music video, a documentary, a public service program, a live program, a pre-recorded program, an interactive program, an enhanced program, an Internet program and a program broadcasted over a network connection. By utilizing real-time interactions between the prior art Ad Inserter and a break planner, the Ad Inserter may be configured to request an ordered list of segments for each break in a programming signal. Further, based upon various parameters unique to a then current situation, a determination may be made as to which commercial or non-segment (hereinafter, “segments”) to insert into a given segment on a real-time basis. By utilizing parameters and other information, the various system and/or method embodiments of the present invention preferably do not depend solely upon the processes of the current state of the art systems in which passive, batch-oriented processes utilize pre-determined schedules to identify which segment is to be inserted into a given break in a given programming signal. Thus, it is to be appreciated that various embodiments of the present invention may utilize batch-oriented processes, pre-determined schedules as well as various parameters in determining which segments to insert into a given programming signal on a real-time or near real-time basis.

More specifically, at least one embodiment of a break planner utilizes a set of rules (which may be defined in an abstract manner) to determine which segment to insert into a particular break in a programming signal. The break planner may utilize these rules, contractual requirements associated with a segment and/or other information to intelligently decide which segment(s) to insert in a given break in a given programming signal. Further, these rules may be implemented based upon a variety of factors and information provided to the break planner by other systems and, for at least one embodiment, are preferably not based upon pre-defined schedules or sequences of events. Examples of the information the break planner may utilize include historical segment placements of segments, profile information for a viewer or group of viewers, real-time events occurring in the media-stream, and other information. As such, various embodiments of the present invention may be configured to be responsive to real-time events such that target advertising may be communicated to viewers or groups of viewers at any time, regardless of the underlying programming signal then being presented and/or as otherwise desired.

Additionally, at least one embodiment of the present invention may be configured to utilize a schedule that is break specific. A break specific schedule preferably comprises an optimal set of segments that are to be presented to a viewer of a given profile. This optimal set ideally is satisfying to the targeted viewer since the programming and other segments being provided is consistent with their interests (i.e., their profile). Similarly, the break specific schedule may also be satisfying and/or appealing to advertisers because it increases the likelihood that a viewer of a given programming signal will watch/read/listen to a given segment and will not surf, skip or otherwise avoid the segment because the viewer(s) have an identified interest in the subject matter of the segment. The break specific schedule may also be appealing and/or satisfying to a producer, because it potentially maximizes advertising revenue for a given programming signal by providing segments that are targeted to viewing audiences interested in such segments. Since this schedule is preferably break specific, is not pre-defined, is not based upon a time of day, is not based upon a program being presented and or is not targeted to a generic audience, this embodiment of the present invention enables programmers to utilize ever finer granularity in targeting programming and segments at users of specific profiles.

Further, in another embodiment of the present invention, the Ad Inserter and the break planner may be in communication with each other. This configuration enables the Ad Inserter to provide up-to-date and even up-to-the-minute information on segments that were and were not inserted into breaks in a programming signal. In short, the logging information normally compiled by the Ad Inserter m ay be provided on a real-time basis to the break planner. By utilizing this configuration, segments that are not inserted into a given break, for whatever reason, may be rescheduled on-the-fly for the next available break in the programming. In this manner, producers of programming signals (i.e., “shows”) may be assured that specific segments will be “aired” during particular sections of a given program. Such assurances reduce the concern for many advertiser, producers and programmers that a time sensitive segment could be delayed for two days or longer before it is actually “aired”.

Further, by providing systems and methods for the real-time break planning of segments, various embodiments of the present invention may also be configured such that the actual lengths of breaks may be adjusted. It is to be appreciated that the length of a break may be measured by at least one of time, frames, bits, bytes, segments, and data. For example, an embodiment of a system of the present invention may be configured to insert a longer time break when an earlier break was interrupted and a segment slotted for the earlier break was not “aired”. It is to be appreciated that such longer breaks may include one or many segments. Similarly, at least one system embodiment may be configured such that longer commercial breaks are possible for segments that do not exactly fit within an industry standard 20 seconds, 30 seconds, 40 seconds or 60 seconds. This feature is especially beneficial in conjunction with live sporting events wherein the time of a given break may vary based upon actions occurring on the field or playing surface. As such, at least one embodiment of the present invention enables programmers to tailor segments to programs as well as programs to segments by configuring systems and or devices (such as an Ad Inserter) to select and insert segments in programming signals. Such segments can be selected for a desired commercial audience and for a desired program while remaining within a general scheduling format of certain programs “airing” at certain times during the day.

For example, one viewer profile for a program may indicate that a population segment between the ages of 17 and 25 will only watch segments for less than 15 seconds before surfing channels. Similarly, for the same program, a viewer profile for ages greater than 60 may indicate that the audience will never surf, and thus, longer segments can be targeted towards such viewers. By utilizing this information, at least one embodiment of the present invention enables programmers and broadcasters to tailor programming and the number and length of segments based upon viewer profiles. Thus, while the senior population may be inclined to view one or two 60 second segments without changing the programming, the younger viewers may be presented with multiple 15 second segments at a more frequent rate during a given programming signal.

Similarly, when a recorded program is being played back on a suitable device, for example, a personal video recorder, another embodiment of the present invention facilitates the targeting of advertising by determining which segments to “air” during a break in the recorded program based upon then current parameters (for example, a location or a time of day at which the playback is occurring). In this manner, advertising can be targeted to viewers regardless of whether the viewing of the program is live or recorded. For example, a segment about an upcoming program following a live sporting event (for example, one announcing what is being presented next on 60 Minutes after a Sunday afternoon football game) can be substituted with an announcement for a Monday evening program which will be “aired” on broadcast/cable television when the previously recorded football game being played back on Monday evening actually ends. This could be accomplished by estimating a time length of the recorded program, adding the time length to the current time, and presenting segments for programs being “aired” after the end of the recorded program.

Therefore, by providing flexibility in both the scheduling of programming, the scheduling of breaks, and the scheduling of segments for such breaks, various embodiments of the present invention facilitate greater targeting of programming to viewers, segments to programming and/or segments to viewers.

Further, one embodiment of the present invention provides a system for inserting a segment into a programming signal, comprising a transmission system which provides a programming signal to at least one viewer; an inserter, connected to the transmission system, which inserts at least one segment into the programming signal; and a break planner which selects and specifies to the inserter the at least one segment from a plurality of segments.

Another embodiment of the present invention provides a media stream planner which provides to an advertisement inserter an indication of at least one segment to insert into a given break in a programming signal, comprising a break planner; for selecting at least one segment for insertion into a break; at least one input port connected to the break planner for receiving at least one parameter related to a segment; and at least one output port for communicating an indication of the selected segment to an advertisement inserter; wherein the break planner utilizes the at least one parameter to select at least one segment for insertion into a given break.

Further, a process is also provided in the present invention for inserting at least one segment into a programming signal comprising: receiving a cue-tone provided in a programming signal; determining based upon at least one parameter, whether a segment has been identified for a break identified by the cue-tone in the programming signal; if a segment has been identified, communicating the segment to a transmission system for insertion into the programming signal at the break point identified by the cue-tone; if a segment has not been identified, requesting a media stream planner to real-time select and identify at least one segment for insertion into the break identified by the cue-tone; obtaining the identified segment; and communicating the identified segment to the transmission system for insertion into the programming signal.

Additionally, a process for determining which segment to insert into a given break in a programming signal comprising: building a list of segments based upon an abstract set of rules, wherein at least one rule specifies how to abstractly order the available segments; sorting the list based upon at least one variable; and selecting a segment at the top of the list as the next segment to insert into a given break in a programming signal.

### BRIEF DESCRIPTION OF THE DRAWING FIGURES

FIG. 1 is a schematic representation of a prior art system utilized to schedule and insert segments in breaks in programming signals.

FIG. 2 is a schematic representation of a system for implementing the real-time commercial scheduling features for at least one embodiment of the present invention.

FIG. 3 is a schematic representation of a system utilized in a personal video recorder implementing another embodiment of the present invention.

FIG. 4 is a flow chart illustrating one embodiment of a process flow of the present invention.

### DETAILED DESCRIPTION OF THE INVENTION

As mentioned previously, at least one embodiment of the present invention provides a system and process for providing real-time scheduling of segments during breaks in programming. Further, various other embodiments of the present invention may be configured such that the placement of the breaks in recorded programming may also be customizable either in advance or on a real-time basis. Similarly, the length of breaks and/or segments, frequency of breaks and/or segments, and timing of breaks and/or segments relative to a program, a time of day or any other parameter may also be customized and/or real-time determined.

Systems and/or processes implementing the various embodiments of the present invention may also be configured to take into consideration various parameters when determining which segments to insert into a specific break. These parameters, which are preferably specified in an advertising campaign, but may be specified otherwise, may include contractual terms, which are also known in the industry as “buy parameters”. Buy parameters may be of any level of refinement. The various embodiments of the present invention support any type and/or level of buy parameters. However, it is to be appreciated that greater refinement in buy parameters may result in fewer placement options for a given segment and vice versa. Further, the system may also utilize other parameters including, for example, a selection criteria from a plurality of available segments, viewer(s) profile data, previous history of segments that have been inserted, time, day, month, year, and other information.

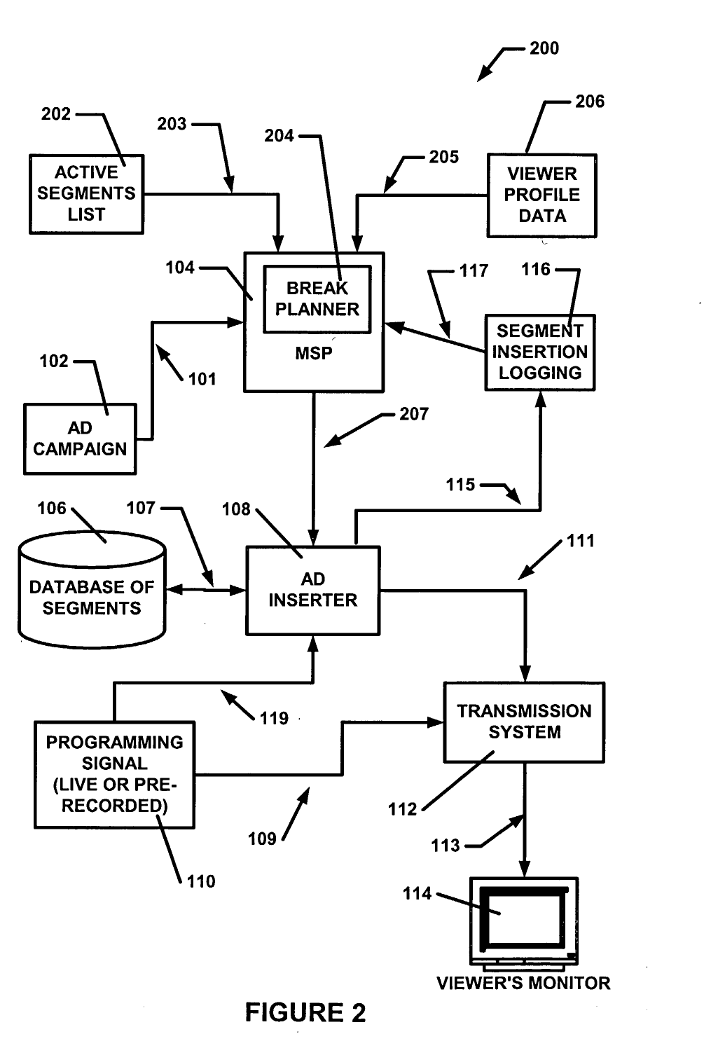

More specifically, FIG. 2 illustrates one embodiment of a system for implementing the present invention. As shown, this system utilizes many of the components utilized in the description of one prior art system. While such prior art system components are described herein it is to be appreciated that the present invention is not limited to using such components and may utilize other components, other systems, other types of signals and/or other system devices and/or processes to facilitate the real-time providing of segments in a given programming signal.

In one specific embodiment, it is anticipated that the present invention may be incorporated directly into an existing MSP (such as, the AdVision system) by the incorporation of the appropriate program codes and software logic into the MSP. However, the present invention is not limited to the AdVision System and/or incorporation into the MSP. Various embodiments of the present invention may be incorporated into any system and/or device which recognizes when breaks in a program are to occur and is capable of inserting a segment and/or a plurality of segments of existing or real-time created content into the break. Such content may include commercials or other advertisements, but may also include non-commercial content. As such, at least one embodiment of the present invention may be incorporated into and/or utilized in conjunction with other advertising placement systems (for example, the Novar™ systems developed by Encoda Systems™, the Compulink System™, and CAMS™). Further, cable head-end systems, broadcaster systems (both local and national) and/or other devices including, for example, personal video recorders and set-top boxes, may also be utilized in conjunction with the various embodiments of the present invention.

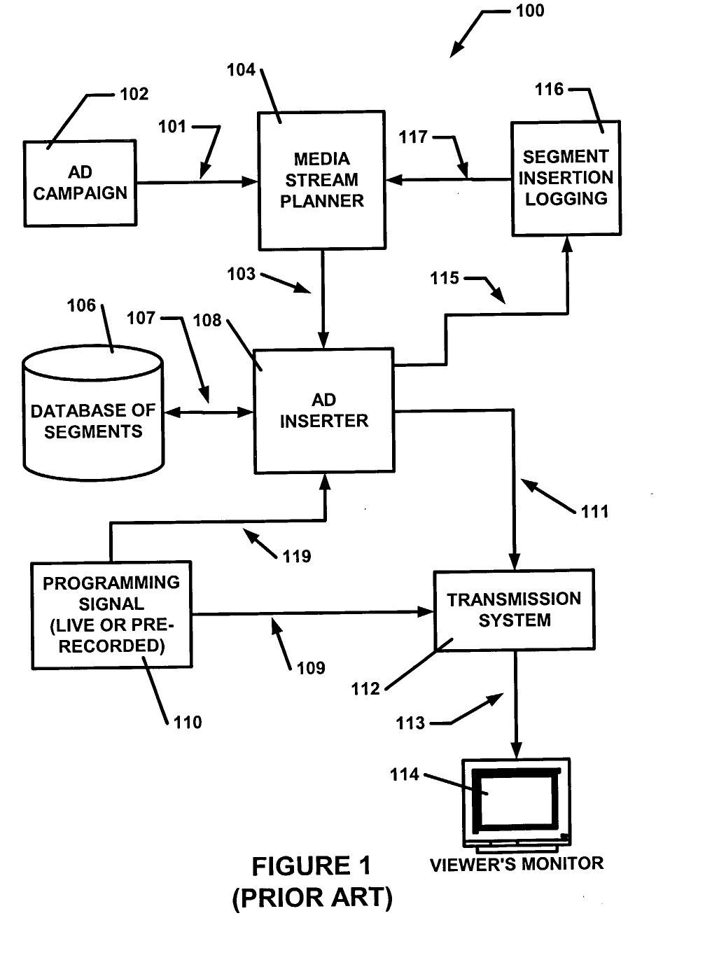

Referring again to FIG. 2, wherein one embodiment of the present invention is shown in an application that utilizes an MSP 104, those components that are common to the prior art MSP system shown in the example of FIG. 1, are indicated in FIG. 2 by the same component designators as are utilized in FIG. 1. Therefore, the embodiment of the present invention shown in FIG. 2 may utilize all, or part of, the MSP 104, the prior art Ad Inserter 108, database of segments 106, programming signal 110, transmission system 112, viewer's monitor 114, segment insertion logging device 116 and the communications connections therebetween.

Additionally, the embodiment of FIG. 2 may also include an active segments list 102, a break planner 204 and viewer profile data 206. As shown, the MSP 104/break planner 204 may be configured to receive inputs from, for example, the ad campaign 102, the segment insertion logging device 116, the active segments list 202 and the viewer profile data 206. This information, in its entirety or in part, may be utilized by the break planner 204 to dynamically determine which segment 107 (selected from, hopefully, a plurality of segments stored in the database 106) to insert into a given programming signal 110 at a given break. It is to be appreciated that for certain programming signals, only one segment or non-segment may be available and/or suitable to insert into the certain programming signal. One embodiment of a process by which the break planner 204 may accomplish these determinations is discussed in greater detail hereinbelow. Based upon these determinations by the break planner 204, the MSP 104 suitably outputs a break plan 207. The break plan 207 may instruct the Ad inserter 108 to insert a specific segment 107 into a given programming signal at a specific break. The break plan 207 may also be utilized for contract compliance purposes, historical purpose and/or otherwise. The operation of the system 200, at this point, continues with the insertion of the segment 107 into the programming signal 110 by the Ad inserter 108, the transmission of the combined signal to the viewer (via the transmission system 112), and the logging of the appropriate data by the segment insertion logging device 116.

More specifically, the present invention, as represented by the embodiment shown in FIG. 2, may be configured to create a real-time schedule (i.e., the break plan) of segments 107 to insert into the programming signal 110. The break plan may be based, in part, upon the contractual requirements information 101 received from the Ad campaign 102. When the present invention is utilized in conjunction with the AdVision system or comparable systems, appropriate interfaces may be provided which enable advertisers to specify Ad campaign information. However, other systems and processes may also be utilized to specify the Ad campaign information.

An example of one set of Ad campaign information is shown below in an XML format. It is to be appreciated, however, that greater or lesser degrees of specificity and/or granularity may be supported and utilized by the present invention in order to define an advertising campaign and that such information may be communicated to the break planner 204 in various formats including, but not limited to, XML.

Example of Ad Campaign Information

<campaign>

<contract>

<contract_id>12345678</contract_id>
<advertiser_id>advertiserX(/advertiser_id>
<contract_item>

<item_num>1</item_num>
<start_time>2001-08-01T22:59:59Z</start_time>
<end_time>2001-08-15T22:59:59Z</end_time>
<avail_class>LOCAL</avail_class>
<priority>7</priority>
<billing_type>PAID</billing_type>
<segment_rate>250.00</segment_rate>
<segment_length>1800</segment_length>
<segment_separation>00:20:00</segment_separation>
<break_position>ANY</break_position>
<break_in_position>ANY</break_in_position>
<break_in_program>ANY</break_in_program>
<industry<code>AUTO</industry_code>
<net_list>

<network_id>ESPN</network_id>
<network_id>ESPN2</network_id>

<net_list>
<exclude_net_list>

<network_id>FAMILY</network_id>
<network_id>LIFE</network_id>

<exclude_net_list>
<event_list>

<event_id>SPORTS CENTER<event_id>
<genre_id>Sports/TalkShow</genre_id>

<event_list>
<segment_quantity>

<min_qty>5</min_qty>
<max_qty>8</max_qty>

<segment_quantity>
<targeting>

<targeting_profile>3</targeting_profile>

<targeting>
<copy_set>

<rotation_type>RANDOM</rotation_type>
<copy_item>
<rotation_ratio>2</rotation_ratio>
<segment_id>AUTO-
MAKE_77579.mpg</segment_id>
<from_time>12:00:00Z</from_time>
<to_time>23:59:59</to_time>
<copy_item>

<copy_set>

<contract_item>

<contract>

<campaign>

As shown in the above example of an XML formatted version of Ad campaign information, the Ad campaign may include any parameter by which a segment can be specified for insertion into a programming signal. More specifically, the above example contains fields for specifying the name of the segment, when the segment may start airing, the end date for airing the segment, what classification of viewers are to receive the segment (for example, national, regional or local), a priority for “airing” the segment (wherein higher priority segments are given priority when allocations of breaks is determined by the break planner), billing information, the rate for the segment, the length in seconds, how much minimum separation is to occur between successive presentations of the segment, which breaks in a program the segment is to be inserted, the industry code and so forth. Further, this information may also include a specification of networks to include (for example, ESPN and ESPN2) and exclude (for example, FAMILY and LIFE) from “airing” the segment as well as specifying the type of program on the selected networks by either, or both, program name and/or program genre. Also, the Ad campaign information may also include the minimum and maximum times the segment is to “air”. It may also include profile information, identifying classes of viewers or groups of viewers, at whom the segment is targeted. Further, rotation information may be provided in which, on a first break, for example, a Truck advertisement is to “air” and on a second break an SUV advertisement is to “air”. In short, the various embodiments of the present invention support the designation of any parameter in the Ad campaign information. The Ad campaign information (in its entirety or in part) and/or other information may be suitably utilized by the break planner 204 to determine which commercial(s) or other programming segment(s) to select for a given break in a programming signal. Further, it is to be appreciated that while the above description is provided in the context of an Ad campaign, similar or the same information may also be provided in the context of non-commercial segments, including, but not limited to public address announcements, documentaries, and other types of content and/or programming.

Additionally, the advertising campaign may also be generated real-time and provided to the break planner 204 on an as needed basis. In one embodiment, the Ad campaign is preferably provided on a daily basis to the break planner. However, in alternative embodiments, Internet connections and other connectivity may be provided to web sites, servers and/or other systems that generate Ad campaign information when desired. The compatibility and the adaptability of the various embodiments of the break planner to changes in the Ad campaign information enables such system and processes to adapt real-time to changes in programming, viewer profiles and other parameters. Such real-time adaptability further enhances the ability of the system to provide segments with high granularity, for example, instead of providing segments only in the aggregate.

As such, at least one embodiment of the present invention preferably utilizes advertising campaign information that is of a greater granularity and particularity than the generic segment name and “airing time” utilized in other systems. This greater granularity ideally provides the break planner with more information from which it can make decisions as to which segment is best suited for a given viewing audience at a given time.

In making this determination, the break planner 204 may also utilize historical prior inserts information 117, viewer profile information 205, segment list information 203 and/or other information. More specifically, since many segments are specified with great particularity as to when, how often, during what programs, on which channels, and the like the segment is to “air” the present invention actively utilizes information compiled and generated by segment insertion logging devices 116. One example of such segment insertion history data is as follows:

<pvr_feedback>

<pvr_id>PVR1</pvr_id>
<downloaded_list>

<downloaded_ad>

<download_time>2001-08-06T00:30:12Z</down-
load_time>
<segment_id>FORD_EXCURSION.mpg</segmentid>

</downloaded_ad>

<downloaded_list>
<screenings_list>

<shown_ad>

<contract_num>1234</contract_num>
<contractitem_num>2</contractitem_num>
<segment_id>FORD EXCURSION.mpg</segment_id>
<screen_time>2001-08-05T03:25:33Z</screen_time>
<event_id>Sports Center</event_id>
<genre_id>Sports/Talk Show</genre_id>
<frame_count>900</frame_count>
<network_id>ESPN</network_id>
<status_code>0</status_code>

</shown_ad>

</screenings_list>
<deleted_list>

<deleted_ad>

<delete_time>2001-07-01T00:00:10Z</delete_time>
<segment_id>FORD ESCORT.mpg</segment_id>

</deleted_ad>

</deleted_list>

</pvr_feedback>.

In this example, the segment inserts history provides detailed information about the segment aired. It is to be appreciated that greater or lesser amounts of information may be utilized and/or provided by such device 116 or comparable devices. Additionally, this information may also be provided to other systems and/or devices and may be utilized by the break planner 204 to provide instructions to such other systems/devices as desired. For example, when the prior inserts history information 117 indicates that a given segment has been “aired” a maximum number of times, the break planner 204 may utilize such information to inform the Ad campaign 102, the active segments list 202, the Ad inserter 108 and/or other systems to no longer consider a given segment for future breaks. Further, it is to be appreciated that the system may also be configured to notify back-end accounting systems and/or other systems of the completion of the advertising campaign contract and to perform other maintenance and file system clean-up activities.

Further, for at least one embodiment of the present invention, log history information is generally not utilized to generate a schedule two days in advance, but may be so utilized if desired. Instead, at least one embodiment of the present invention utilizes the log history information to actively determine which segment to “air” in a next available break. As such, segments which are not aired at a designated time, for whatever reason, may be actively rescheduled as soon as possible. This is possible, via various embodiments of the present invention, because the determination of which segment to insert into a given break in a given programming signal may be accomplished real-time.

Referring again to FIG. 2, the break planner 204 may also utilize viewer profile information 205. This information 205 may be generated by a viewer profile data system 206. In one embodiment, such information is generated by a third party Internet site. In other embodiments, such information is generated by the break planner 204 itself or by other local or remote devices and/or systems. Viewer profile information may also be generated at the viewer's end, for example by a personal video recorder (PVR), a set-top box, a computer or otherwise. As such, it is to be appreciated that various embodiments of the present invention may utilize viewer profile information, the generation of which is beyond the scope of the present invention and therefore is not discussed in greater detail herein. However, at least one embodiment of a user profile system is described in U.S. patent application Ser. No. 09/409,305, which is entitled “Enhanced Video Programming System and Method Utilizing User-Profile Information” and was filed on Sep. 29, 1999, the entire contents of which are incorporated herein by reference.

Another embodiment of the break planner may also be configured to receive an indication of the active segments via a segment list 203. An example of such a segment list, in XML, is as follows:

<segment_list>

<segment_item>

<segment_id>FORD_7735.mpg</segment_id>
<profile_num>1</profile_num>
<profile_num>3</profile_num>

<segment_item>

</segment_list>

The segment list 203 generally and preferably contains an indication of those segments that are available for insertion into a given programming signal. Depending upon the storage capacity of the database of segments 106 (which may be local or remote to the break planner 204 and/or the Ad inserter 108), the segment list 203 may be larger or smaller than the contract requirements 101 provided to break planner 204 at any given time. For example, when the break planner 204 is implemented in a set top box or personal video recorder, fewer segments may be available than when the break planner is located at a cable head-end or broadcast station.

As such, the break planner suitably determines, based upon the available segments designated on the segment list, the contractual requirements 201, the viewer profile (if any) and the prior inserts history 117, which segment to insert into a given break in a programming signal. If data storage devices of essentially unlimited storage capacity are accessible by the break planner 204, then it is to be appreciated that the segment list 203 may be quite long. Similarly, with limited storage capacity, the segment list 203 may be quite small. Thus, the various system and process embodiments of the present invention may suitably determine which segment(s) (or other segment(s) or programming) to insert into a given break, on a real-time basis when so desired, based upon the list of available segments, contractual requirements for various Ad campaigns, prior inserts history, viewer profile information and/or other information.

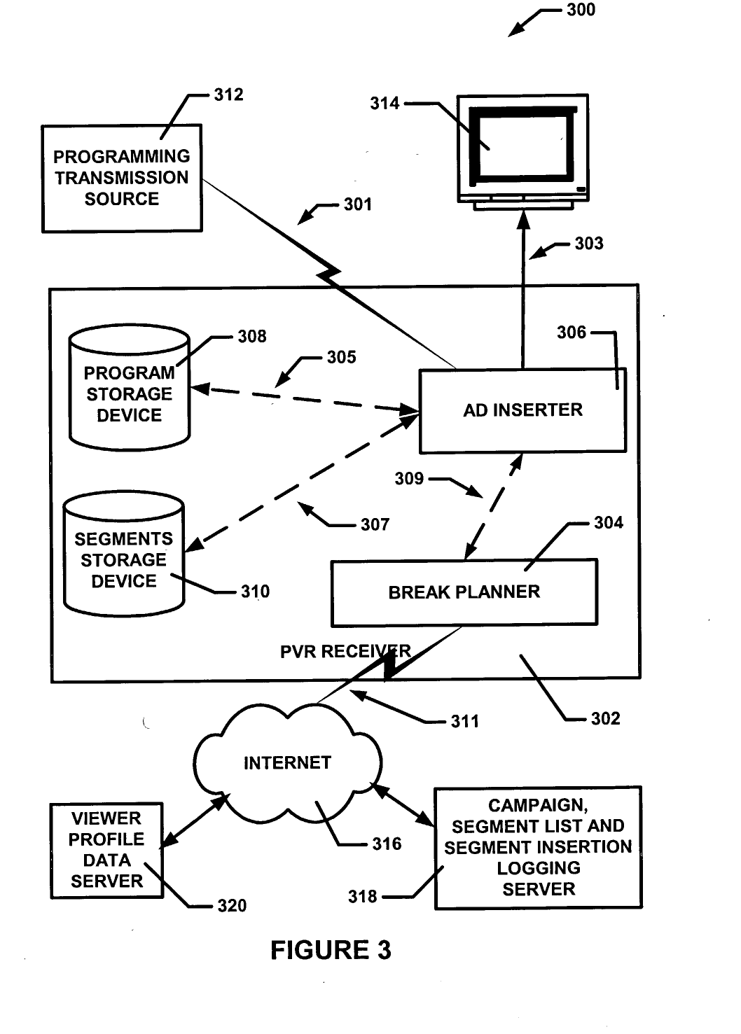

Referring now to FIG. 3, another embodiment of a system 300 implementing the present invention is depicted. In this system 300, the break planner 304 is incorporated into a set top box, for example, a PVR 302. As is well known in the art, a PVR commonly receives a programming signal 301 from a transmission source 312. The communications medium carrying the programming signal 301 may be any medium known in the art, including, but not limited to, cable systems, broadcast systems, satellite systems, Internet and other network connections, and/or play-backs from pre-recorded mediums, for example, a magnetically recorded medium, such as a VHS tape, an optically recorded medium, such as a Digital Versatile Disc (DVD), or any other type of medium. Further, it is to be appreciated that the programming signal 301 may be live or pre-recorded.

Further, the PVR receiver 302 may be configured, when receiving the programming signal 301, to record/save the programming signal 301 in a storage device 308, present the programming signal 303 to a viewer via a monitor 314 and/or both record and present the programming signal. Further, the Ad Inserter 306 is suitably configured to receive the programming signal 301 and determine whether the received signal contains programming signals 305 for saving in the program storage device 308, segments 307 for saving in the segments storage device 310 and/or both. Further, it is to be appreciated that the program storage device 308 and the segments storage device may be provided in the same or many storage mediums. Additionally, in this embodiment a broadcaster may desire to communicate segments to the PVR 302 via the same communications medium utilized by the programming signal 301. As such, the PVR 302 may not be required to have multiple communications capabilities and may receive segments from the programming transmission source and then save the segments in a storage device 310 for later insertion into the program and segments signal 303 provided to the viewer. Further, the program storage device 308 and/or the segments storage device 310 ma be provided via a compact disc, a laser disc, a digital versatile disc, a flash memory device, a magnetically recordable medium, an optically recordable medium and the like.

The PVR 302 may also include a break planner 304. The break planner 304 may be configured to receive from the programming transmission source 312, via the programming signal 301, information utilized by the break planner 304 to determine which segment to insert in a given program and segments signal 303. In such an embodiment, the PVR 302 is not required to have duplex communications with a programming source or other external source. Such a configuration may be desirable where communications are easily received (for example, via a satellite signal) but transmission systems are not available to the PVR (for example, when on a plane, boat, in a third world country, and the like).

In at least one preferred embodiment, however, duplex communications capabilities are available for the PVR 302. In one such duplex communications embodiment, the break planner 304 is configured to establish a communications link 311, via the Internet 316 or another network connection, with a viewer profile data server 320 and/or a campaign, segment list and segment insertion logging server 318 or similar systems. The viewer profile data server 320 suitably provides viewer profile information that may be utilized by the break planner 304 to determine which segment to insert into either a live programming signal 301, a programming signal obtained from the program storage device 308, or a combination of a live and recorded programming signal (for example, a signal which utilizes stored data in conjunction with live data/signals to provide customized programming to a given viewer or group of viewers). Similarly, the campaign, segment list and segment insertion logging server 318 provides Ad campaign information, segment list information and/or prior inserts history information. It is to be appreciated that the server 318 may be broken out into separate servers or combinations thereof.

Further, the Ad inserter 306 and break planner 304 are preferably adaptable and compatible with numerous devices and are not limited to implementations in only a PVR or similar device. One set of program code that enables the Ad inserter 306 and/or break planner 304 to be compatible with such numerous devices is as follows:

<config_data>

<pvr_id>PVR1</pvr_id>
<url_poll_rate>10</url_poll_rate>
<traffic_url>http://192.168.0.8/AdVision/</traffic_url>
<adco_url>http://192.168.0.9/AdCo/</adco_url>
<segment_path>/pvr/segments/</segment_path>
<profile_file>/pvr/data/profile.xml</profile_file>
<segmentlist_file>/pvr/data/segmentlist.xml</segmentlist_file>
<campaign_file>/pvr/data/campaign.xm</campaign_file>
<log_path>/pvr/logs/</log_path>

</config_data>

This configuration information may be stored by the PVR or similar device in a configuration file, such as, /pvr/config.xml. However, for systems that are not compatible with XML and/or the hyper-text transfer protocol, other data file formats, configuration information, and/or storage schemes may be utilized. Further, in the embodiment shown in FIG. 3, the PVR 302 preferably includes a processor that utilizes the Linux operating system or another operating system while providing full computing capabilities, programmability and similar functions.

Additionally, those skilled in the art will appreciate that the above specific configuration routine includes pointers and other commands identifying where various file elements may be obtained, including, the location of profile information, segment list information, campaign information and segment list history information. These pointers may point at Internet server addresses, local file database addresses and even “words” in a digital or analog transmission stream.

As discussed above, this embodiment and other embodiments allow a break planner 304 to obtain profile information. The profile information may very with time, programming schedule, and other variables. Preferably, the profile information for a given day and/or program is determined by an Internet or other network based server 320, thereby alleviating the PVR 302 from such processing responsibilities. The profile server 320 suitably communicates such profile information to the break planner in an appropriate XML formatted message. One example is as follows:

<profile_definition>

<pvr_id>PVR1</pvr_id>
<profile_num>3</profile_num>

</profile_definition>.

Further, in this embodiment, the profile is communicated in terms of a profile number (for example, “3”) which suitably instructs the break planner 304 to select a segment that corresponds to the designated profile number. However, other profile identifying schemes may be utilized as desired.

While this embodiment preferably obtains profile information from an Internet based server, it is to be appreciated that such profile information may also be generated by the PVR 302 itself. In such an embodiment, a communications link with the profile server 320 is not needed, and thus concerns with privacy issues are not raised since private information is not communicated to third parties.

The break planner 302 for this embodiment and the previously mentioned embodiments preferably may be implemented utilizing a Java 2 program. In one embodiment, the PVR will (internally) call a server supplied Java class library, “BreakPlanner.selectSegments”, to determine the list of one or more segments to play for each break in the program. The selectSegments process will be called once for each break into which segments may be inserted. This may be done in succession prior to beginning playback of the event or throughout the event just prior to a break occurring in real-time. Preferably, the BreakPlanner class will be implemented in Java 2 with an appropriate public interface, for example, “package com.profile_provider.pvrmodel”. This class suitably encapsulates the function of determining the optimal set of ads to play for a given break, for example:

public class BreakPlanner {

public BreakPlanner(
string campaign_filename, string log_filename,
string segmentlist_filename, int profile_num)
PlayListElement[] Playlist.

Further, the coding also includes a PlayListElement class that defines a structure for the individual contract segments that are returned from the selectSegments process. An example of this class is:

public class PlayListElement{

public PlayListElement(
int ContractNum, int ContractItemNum, string SegmentID)

public int getContractNum( )
public int getContractItemNum( )
string getSegmentID( )

}

The selectSegments process also accepts arguments describing the advertising opportunity (i.e., the break) and fills the playlist array of PlayListElement objects defining the segments to insert in the break. The caller also may specify the length of the break (in frames) for real-time events or may use a value of “0” to indicate that any length break may be returned. The return value indicates the length of the break in frames or in terms of a negative valued error code. An example of such code is:

long selectSegments(

| | |
|---|---|
| long UTC, | // datetime at which the break is to occur |
| string netID, | //DBMS NetworkID from which event played |
| string eventTitle, | // DBMS ProgramTitle of the event |
| string eventGenre, | // DBMS ProgramGenre of the event |
| int breaknum, | // ordinal position of this break in the event (1+) |
| long breaklen ) | // count of frames in break (0=any length OK) |
| } | |

When utilizing the selectSegments process, the break planner may suitably consult the saved XML data files containing the PVR profile, active campaign, active segments, and segment list history (i.e., the PVR_feedback file) to choose the best set of segments to fill the specified break. At this point, the SelectSegments program returns an ordered list of PlayListElemets to insert for the break. The break planner then inserts the segments and logs the PlayListElements to the active log file.

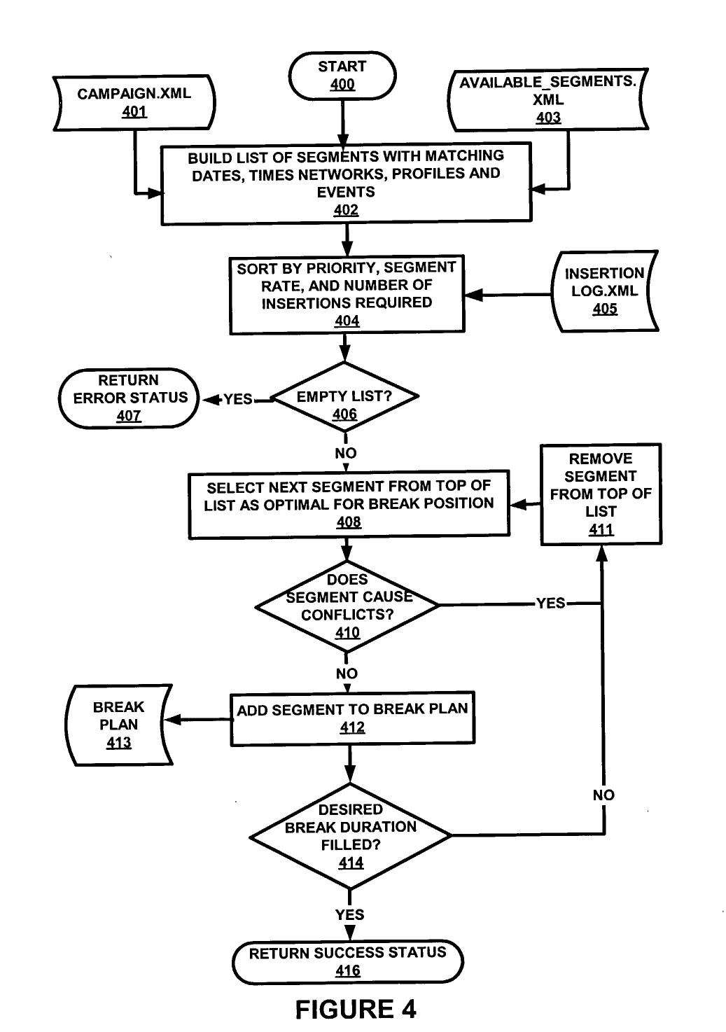

Referring now to FIG. 4, another process by which the break planner may determine which segment to insert into a given break in a programming signal is presented. As shown, this process starts with the calling of the break planner routine by the Ad inserter or the operating system of the PVR or other device in which the break planner is being implemented. The calling of the break planner routine ideally occurs upon the recognition of a Cue-Tone or other indicator that a break will soon occur (Block 400). However, the break planner routine may also be called at other times or based upon other events. Once initialized, the break planner then builds a list of segments with matching dates, times, networks, profiles and events (Block 402). In building this list, the break planner suitably utilizes information obtained from an Available_Segments.xml data file (which may be obtained from a server or encoded in the programming signal) (Block 403). The break planner may also utilize information obtained from the Campaign.xml data file (which was preferably previously provided via the campaign server) (Block 401).

Once the list is built, the break planner then sorts the list by priority, segment rate, and number of insertions required (Block 404). It is to be appreciated that in other embodiments the sorting of the list may take into account other factors and parameters. Further, the break planner may also utilize information from the InsertionLog.xml data file (Block 405) when sorting the list.

At this point the break planner then determines whether the list is empty (Block 406). If the list is empty, an error status is returned (Block 407). If the list is not empty, the break planner selects the next segment from the top of the list as the segment that is optimal for the current break position, if one then exists, or the next available break (Block 408).

Next, the break planner determines whether the selected segment causes any conflicts (Block 410). It is to be appreciated that a segment may cause a conflict in a variety of manners. For example, an auto advertiser generally does not prefer for one of their advertisements to be immediately followed by a competitor's advertisement (for example, a Ford commercial generally should not be followed by a Chevy commercial). Similarly, a segment may cause a conflict if changes in the break time, length, program, or other factor changes from the time of selection of the segment to the actual time of “airing” the segment. If the segment causes a conflict, the break planner removes the segment from the top of the list (Block 411).

If the segment does not cause a conflict, the process continues with the break planner adding the segment to the break plan (Block 412). The break plan is then suitably communicated (as desired or based upon some predetermined schedule) to the Ad inserter (Block 413). Additionally, the break planner then ideally determines whether the desired break duration has been filled by the selected segment (Block 414). If the break duration is not filled, the current segment (which was placed in the break plan) is removed from the top of the list and the processing continues with Block 411. If the break duration is filled, the break planner returns a success status (Block 416). Processing is then restarted when the next instance of a Cue-tone is detected by the Ad inserter or other device.

In other embodiments, the process may also include the optional steps of adjusting break lengths, programming signal lengths (for example, terminating a program in mid-stream when a program of higher priority is to be aired), or otherwise manipulating the presentation of programming signals and the insertion of commercial and/or non-segments therein.

As such, the present invention includes and has been described in the context of various system and process embodiments. The present invention, however, is not to be construed as being limited to the embodiments shown herein and includes any systems or processes within the spirit and scope of the present invention as expressed herein and in the claims and drawing figures.

1. A system for inserting a segment into a programming signal, comprising:
a transmission system which provides a programming signal to at least one viewer;
an inserter, connected to the transmission system, which inserts at least one segment into the programming signal; and
a break planner which selects and specifies to the inserter the at least one segment from a plurality of segments.

2. The system of claim 1, wherein the programming signal includes a live signal.

3. The system of claim 1, wherein the programming signal includes a pre-recorded signal.

4. The system of claim 1, wherein the transmission system further comprises a programming signal transmission system selected from the group consisting of a broadcast system, a cable head-end, a satellite transmission system, an Internet server, and a network server.

5. The system of claim 1, wherein the transmission system further comprises a personal video recorder.

6. The system of claim 5, wherein the personal video recorder obtains the programming signal from at least one of an earlier transmitted signal and a computer readable medium.

7. The system of claim 6, wherein the computer readable medium further comprises at least one a compact disc, a laser disc, a digital versatile disc, a flash memory device, a magnetically recordable medium and an optically recordable medium.

8. The system of claim 1, wherein the segment further comprises a commercial segment.

9. The system of claim 1, wherein the segment further comprises a non-commercial segment.

10. The system of claim 1, wherein the programming signal further comprises at least one a news program, a sports program, a sit-com program, a featured presentation program, a movie, a drama program, a game show program, a music video, a documentary, a public service program, a live program, a pre-recorded program, an interactive program, an enhanced program, an Internet program and a program broadcasted over a network connection.

11. The system of claim 1, wherein the inserter further comprises an advertisement inserter.

12. The system of claim 11, wherein the advertisement inserter further comprises at least one of an AdVision system, a Novar system, a Compulink System and a CAMS system.

13. The system of claim 1, wherein the break planner is provided in a media stream planner.

14. The system of claim 1, wherein the break planner utilizes at least one of a segment list, contractual requirements specified for an advertising campaign, a history of previous segment insertions into a programming signal and viewer profile information in selecting the at least one segment.

15. The system of claim 14, wherein the inserter utilizes at least one rule to select the at least one segment.

16. The system of claim 15, wherein at least one of the at least one rules utilized by the inserter provides for the checking of conflicts between a previous segment and a subsequent segment.

17. The system of claim 1, wherein the segment further comprises at least one other programming signal.

18. The system of claim 1, wherein the break planner instructs the inserter to provide a break of a given length in the programming signal.

19. The system of claim 18, wherein the length of the break is measured by at least one of time, frames, bits, bytes, segments, and data.

20. A media stream planner which provides to an advertisement inserter an indication of at least one segment to insert into a given break in a programming signal, comprising:
a break planner; for selecting at least one segment for insertion into a break;
at least one input port connected to the break planner for receiving at least one parameter related to a segment; and
at least one output port for communicating an indication of the selected segment to an advertisement inserter;
wherein the break planner utilizes the at least one parameter to select at least one segment for insertion into a given break.

21. The media stream planner of claim 20, wherein the break planner further comprises a plurality of computer program instructions which are provided to and configure the media stream planner to select the at least one segment based upon an abstract set of rules.

22. The media stream planner of claim 21, wherein the computer program instructions are provided to the media stream planner by at least one medium selected from the group consisting of: a magnetically recordable medium, an optically recordable medium, a computer data signal sent over a network or telephone connection, and a propagated signal sent via at least one of a cable system, a satellite system or a broadcast system.

23. The media stream planner of claim 21 wherein the computer program instructions are encoded into a memory device accessible by the media stream planner.

24. The media stream planner of claim 21, wherein the computer program instructions further comprise:
generating a list of segments;
sorting the generated list of segments by at least one variable;
selecting a highest listed segment as the optimal segment to insert into the break; and
communicating the selected segment to the advertisement inserter.

25. The media stream planner of claim 24, wherein the instructions further comprise determining whether the selected segment conflicts with another segment; and if a conflict exists, selecting the next highest listed segment on the list and communicating the next highest listed segment instead of the highest listed segment to the advertisement inserter.

26. The media stream planner of claim 25, wherein the instructions are implemented whenever the advertisement inserter requests a break plan.

27. The media stream planner of claim 26, wherein the advertisement inserter requests a break plan every time a cue-tone is detected in a programming signal.

28. The media stream planner of claim 27, wherein the programming signal includes at least one break into which at least one segment selected by the break planner is inserted.

29. The media stream planner of claim 20, wherein the segment further comprises at least one of a commercial segment and a non-commercial segment.

30. The media stream planner of claim 29, wherein the segment is generated real-time.

31. The media stream planner of claim 29, wherein the segment is pre-recorded and is obtained from a database of segments upon receiving the indication of the selected segment from the break planner.

32. The media stream planner of claim 20, wherein the input port provides a connection to an ad campaign providing at least one contractual requirement for an ad campaign as a parameter.

33. The media stream planner of claim 32, wherein the ad campaign includes at least one contractual requirement selected from the group consisting of: a contract number identifier, an advertiser identifier, an item number, a start time for a segment, an end time for a segment, an available class, a priority, a billing type, a segment rate, a segment length, a segment separation, a break position, a break in position, a break in program, an industry code, a network listing, an excluded network listing, an event listing, an event identification, a genre identification, a segment quantity, a minimum segment quantity, a maximum segment quantity, a targeting profile indicator, a rotation type, a rotation ratio, a segment identification, a from-time designator, and a to-time designator.

34. The media stream planner of claim 33, wherein the break planner utilizes at least one of the contractual requirements in generating a break plan on a real-time basis.

35. The media stream planner of claim 20, wherein the input port provides a connection to at least one segment insertion logging device providing at least one parameter related to a prior inserts history for a segment.

36. The media stream planner of claim 35, wherein the at least one parameter related to a prior inserts history for a segment further comprises at least one selected from the group consisting of: a downloaded list, a downloaded segment, a download time, a segment identification, a screenings list, a shown segment identification, a contract number, a contract item number, a screen time, an event identification, a genre identification, a frame count, a network identification, a status code, a deleted segment listing, a deletion time, and an identification of a deleted segment.

37. The media stream planner of claim 36, wherein at least one of the parameters is obtained from a personal video recorder device.

38. The media stream planner of claim 36, wherein at least one of the parameters is obtained from the advertisement inserter after the insertion of a segment into a break by a transmission system.

39. The media stream planner of claim 20, wherein the input port provides a connection to a viewer profile data system providing viewer profile information as the at least one parameter.

40. The media stream planner of claim 39, wherein the viewer profile information is generated by at least one of a viewer profile data system, a third party Internet site, the break planner, a personal video recorder, a local system and a remote system.

41. The media stream planner of claim 20, wherein the input port provides a connection to an active segments list providing a listing of at least one segment as the at least one parameter.

42. The media stream planner of claim 41, wherein at least one segment on the active segments list further comprises an indication of at least one parameter selected from the group consisting of: a segment identification and a profile number.

43. A process for inserting at least one segment into a programming signal comprising:
receiving a cue-tone provided in a programming signal;
determining based upon at least one parameter, whether a segment has been identified for a break identified by the cue-tone in the programming signal;
if a segment has been identified, communicating the segment to a transmission system for insertion into the programming signal at the break point identified by the cue-tone;
if a segment has not been identified, requesting a media stream planner to real-time select and identify at least one segment for insertion into the break identified by the cue-tone;
obtaining the identified segment; and
communicating the identified segment to the transmission system for insertion into the programming signal.

44. The process of claim 43, wherein the process is repeated more than once in order to insert more than one segment into the break identified by the cue-tone.

45. The process of claim 43, wherein the media stream planner includes a break planner and whereupon receipt of the request to real-time select and identify at least one segment, the break planner utilizes at least one parameter provided by at least one of an ad campaign, an active segments list, a profile database, and a prior inserts history to select and identify the at least one segment for insertion into the break identified by the cue-tone.

46. The process of claim 43, wherein the segment is obtained from a database of segments.

47. The process of claim 43, wherein the segment is generated real-time and is obtained from a system generating the real-time segment.

48. The process of claim 47, wherein the segment is generated real-time on a computer system accessible via a network.

49. The process of claim 48, wherein the computer system further comprises one accessible via a Web site and the network further comprises one accessible via the Internet.

50. A process for determining which segment to insert into a given break in a programming signal comprising:
building a list of segments based upon an abstract set of rules, wherein at least one of the rules specifies one criteria for abstractly ordering the available segments on a real-time basis;
sorting the list based upon at least one variable; and
selecting a segment at the top of the list as the next segment to insert into a given break in a programming signal.

51. The process of claim 50, wherein the operation of building a list of segments further comprises:
at least one data gathering operation further comprising:
obtaining advertising campaign information;
obtaining active segments information;
obtaining prior inserts history information;
obtaining viewer profile information; and
utilizing at least one parameter from any of the foregoing information types to generate a list of segments wherein the list satisfies at least one of the abstract rules.

52. The process of claim 51, wherein at least one of the abstract rules specifies ordering the list based upon at least one of dates, times, networks, profiles and events.

53. The process of claim 50, wherein the operation of sorting the list based upon at least one variable utilizes at least on variable selected from the group consisting of a priority for a segment, a segment rate and a number of insertions required.

54. The process of claim 53, wherein at least one of the variables is provided in an insertion log.

55. The process of claim 50, further comprising:
determining whether any conflicts exist between a selected segment and either a previous segment or a subsequent segment to be presented in the programming signal.

56. The process of claim 55, wherein when a conflict exists, the process further comprises:
selecting a segment next on the list as the segment to be inserted into the given break in the programming signal.

57. The process of claim 56, wherein the process further comprises:
determining whether the segment selected to be inserted into the given break in the programming signal utilizes all of the time provided in the given break; and
if so, awaiting the next cue-tone; and
if not, repeating the process with selecting additional segments until all of the time provided in the given break is filled with segments.

58. The process of claim 56, wherein the process further comprises:
determining whether the segment selected to be inserted into the given break in the programming signal utilizes all of the time provided in the given break or requires more time in the break and
if more time is required, increasing the length of the break to accommodate the selected segment; and
if less time is required, shortening the length of the break to accommodate the selected segment.
